(19) United States
(12) Patent Application Publication
(10) Pub. No.: US 2024/0222982 A1
(43) Pub. Date: Jul. 4, 2024

(54) SERIES AND PARALLEL BATTERY SYSTEM SUPPORTING ZERO-VOLTAGE CHARGING, LITHIUM BATTERY, AND CHARGING METHOD

(71) Applicant: ARI ENERGY (HUIZHOU) CO.,LTD, Huizhou (CN)

(72) Inventor: Yingqiang ZHENG, Huizhou (CN)

(73) Assignee: ARI ENERGY (HUIZHOU) CO.,LTD, Huizhou (CN)

(21) Appl. No.: 18/495,082

(22) Filed: Oct. 26, 2023

(30) Foreign Application Priority Data
Jan. 4, 2023 (CN) 202310031496.8

(51) Int. Cl. H02J 7/00

(52) U.S. Cl. CPC H02J 7/0013; H02J 7/0047; H02J 7/007182

(57) ABSTRACT

Disclosed are a series and parallel battery system supporting zero-voltage charging, a lithium battery, and a charging method. The lithium battery for the series and parallel battery system supporting zero-voltage charging includes: a battery cell assembly, a main charge and discharge switch circuit and a trickle charge switch circuit; the main charge and discharge switch circuit is provided in series between the battery cell assembly and a power supply end.

### CROSS-REFERENCE TO RELATED APPLICATIONS

The present application claims priority to Chinese Patent Application No. 202310031496.8, filed on Jan. 4, 2023, the entire contents of which are incorporated herein by reference.

### TECHNICAL FIELD

The present application relates to the technical field of lithium battery charging, and in particular to a series and parallel battery system supporting zero-voltage charging, a lithium battery, and a charging method.

### BACKGROUND

Due to their higher energy density and longer cycle life, lithium batteries have gradually replaced lead-acid batteries and become the mainstream application in many fields.

During the use of lithium batteries, zero voltage in single cells or series and parallel battery systems often occurs due to user's negligence or lack of effective maintenance. When it happens to the battery or the battery system, usually the battery can only be restored to normal by the manufacturer or under the guidance of the manufacturer. The user cannot take measures to restore the battery to normal, causing inconvenience of use.

### SUMMARY

The main purpose of the present application is to provide a lithium battery and charging method for series and parallel battery system supporting zero-voltage charging, aiming to solve the problem that when the battery is in zero voltage, it is difficult for the user to take measures to restore the battery to normal, thereby causing inconvenience of use.

In order to achieve the above object, the present application provides a lithium battery for a series and parallel battery system supporting zero-voltage charging, including: a battery cell assembly, a main charge and discharge switch circuit and a trickle charge switch circuit;
the main charge and discharge switch circuit is provided in series between the battery cell assembly and a power supply end, and configured to control an electrical connection between the battery cell assembly and the power supply end in response to receiving a charge/discharge control signal; and
the trickle charge switch circuit is provided in parallel with the main charge and discharge switch circuit, and configured to conduct a path between the battery cell assembly and the power supply end in response to that the main charge and discharge switch circuit disconnects the electrical connection between the battery cell assembly and the power supply end, so as to trickle charge the battery cell assembly in response to that the power supply end is connected to a charger.

In an embodiment, the lithium battery for the series and parallel battery system supporting zero-voltage charging further includes: a battery management assembly and a power selection circuit;
an input end of the power selection circuit is respectively connected to the battery cell assembly and the power supply end, an output end of the power selection circuit is connected to the battery management assembly, and the power selection circuit is configured to select one of the battery cell assembly and the power supply end to supply power to the battery management assembly according to a voltage value of the battery cell assembly.

In an embodiment, the lithium battery for the series and parallel battery system supporting zero-voltage charging further includes a trickle charge detection circuit;
a detection end of the trickle charge detection circuit is connected to the trickle charge switch circuit, an output end of the trickle charge detection circuit is connected to the battery management assembly, and the trickle charge detection circuit is configured to detect a working state of the trickle charge switch circuit and output a corresponding trickle charge detection signal to the battery management assembly; and
the battery management assembly is further configured to identify the working state of the corresponding trickle charge switch circuit according to the trickle charge detection signal.

In an embodiment, the battery cell assembly includes a plurality of battery cell assemblies, and the lithium battery for the series and parallel battery system supporting zero-voltage charging further includes:
a battery voltage detection circuit is connected to the battery cell assembly and configured to detect a voltage of the battery cell assembly to obtain a voltage of the plurality of battery cell assemblies and output a battery voltage detection signal; and
the battery management assembly is further configured to communicate with the charger during power-on operation, control the trickle charge switch circuit to operate and output a real-time trickle current request to the charger in response to that the voltage is determined to be lower than a preset voltage according to the battery voltage detection signal, and control the trickle charge switch circuit to stop in response to that the voltage is determined to be higher than or equal to the preset voltage according to the battery voltage detection signal.

In an embodiment, the lithium battery for the series and parallel battery system supporting zero-voltage charging further includes a current detection circuit;
a detection end of the current detection circuit is connected to the battery cell assembly, and an output end of the current detection circuit is connected to the battery management assembly; the current detection circuit is configured to detect a current flowing through the battery cell assembly and output a current detection signal; and
the battery management assembly is further configured to output the real-time trickle current request to the charger according to the current detection signal.

In an embodiment, the trickle charge switch circuit includes a current-limiting resistor, a switching tube and a relay, one end of the current-limiting resistor is connected to the power supply end, a first end of the switching tube is connected to one end of the relay, a second end of the switching tube is connected to the other end of the current-limiting resistor, and the other end of the relay is connected to the battery cell assembly.

The present application also provides a series and parallel battery system supporting zero-voltage charging, including a plurality of lithium batteries for the series and parallel battery system supporting zero-voltage charging connected in series and parallel to each other.

In an embodiment, the charging method for the series and parallel battery system supporting zero-voltage charging includes:
in response to that the main charge and discharge switch circuit disconnects the electrical connection between the power supply end and the battery cell assembly, conducting, by the trickle charge switch circuit, the path between the battery cell assembly and the power supply end, so as to trickle charge the battery cell assembly in response to that the power supply end is connected to the charger.

In an embodiment, the charging method for the series and parallel battery system supporting zero-voltage charging further includes:
in response to that the battery management assembly connected to the charger is connected to an auxiliary power supply provided by the charger and powered on, communicating the battery management assembly with the charger and outputting a trickle charge current request to the charger according to the battery voltage detection signal; and
connecting the battery management assembly connected to the power selection circuit to one of the battery cell assembly and the power supply end to power on.

In an embodiment, the charging method for the series and parallel battery system supporting zero-voltage charging further includes:
in response to that the voltage of the battery cell assembly connected to the battery management assembly is determined to be higher than or equal to the preset voltage according to the battery voltage detection signal, controlling, by the battery management assembly, the trickle charge switch circuit to stop and outputting a charging control signal to the main charge and discharge switch circuit to control the electrical connection between the power supply end and the battery cell assembly.

In the present application, in response to that main charge and discharge switch circuit disconnects the electrical connection between the battery cell assembly and the power supply end, that is, the voltage of the battery cell assembly is zero voltage, the trickle charge switch circuit conducts the path between the battery cell assembly and the power supply end, so as to trickle charge the battery cell assembly in response to that the power supply end if connected to the charger. The charger then uses a low current to trickle charge the battery cell assembly so that the lithium battery can resume normal operation on its own, which solves the problem that lithium batteries cannot be charged when in zero voltage due to long-term over-discharge and other reasons, and improves the user's convenience.

### BRIEF DESCRIPTION OF THE DRAWINGS

In order to illustrate the technical solutions in the embodiments of the present application or in the related art more clearly, the following briefly introduces the accompanying drawings required for the description of the embodiments or the related art. Obviously, the drawings in the following description are only part of embodiments of the present application. For those skilled in the art, other drawings can also be obtained according to the structures shown in these drawings without any creative effort.

FIG. 1 is an overall block view of a lithium battery for a series and parallel battery system supporting zero-voltage charging according to an embodiment of the present application.

FIG. 2 is a schematic module view of the lithium battery for the series and parallel battery system supporting zero-voltage charging according to an embodiment of the present application.

FIG. 3 is a circuit view of a trickle charge switch circuit of the lithium battery for the series and parallel battery system supporting zero-voltage charging according to an embodiment of the present application.

FIG. 4 is a schematic module view of a series and parallel battery system supporting zero-voltage charging according to an embodiment of the present application.

FIG. 5 is a schematic module view of the series and parallel battery system supporting zero-voltage charging according to an embodiment of the present application.

FIG. 6 is a schematic flowchart of a charging method for the series and parallel battery system supporting zero-voltage charging according to an embodiment of the present application.

The realization of the objective, functional characteristics, and advantages of the present application are further described with reference to the accompanying drawings.

### DETAILED DESCRIPTION OF THE EMBODIMENTS

The technical solutions of the embodiments of the present application will be described in more detail below with reference to the accompanying drawings. It is obvious that the embodiments to be described are only some rather than all of the embodiments of the present application. All other embodiments obtained by those skilled in the art based on the embodiments of the present application without creative efforts shall fall within the scope of the present application.

In addition, the descriptions of “first”, “second”, etc. in the present application are only for the purpose of description, and should not be construed as indicating or implying relative importance or implicitly indicates the number of technical features indicated. Thus, a feature delimited with “first”, “second” may expressly or implicitly include at least one of that feature. In addition, the technical solutions between the various embodiments can be combined with each other, but must be based on the realization by those skilled in the art. When the combination of technical solutions is contradictory or cannot be realized, it should be considered that the combination of such technical solutions does not exist or fall within the scope of protection claimed in the present application.

At present, lithium batteries have gradually replaced lead-acid batteries in many fields and become the mainstream application due to their higher energy density and longer cycle life. During the use of lithium batteries, zero voltage in single cells or series and parallel battery systems often occurs due to user's negligence or lack of effective maintenance, that is, when the lithium battery system's power is completely zero or close to zero for some reason, the internal battery management system will stop working due to low voltage, all power input and output channels will be turned off, and the normal charging will not be possible. Once it happens, the battery can only be restored to normal through the manufacturer or under the guidance of the manufacturer. The user cannot take measures to restore the battery to normal, causing inconvenience.

In order to solve the above problems, the present application provides a series and parallel battery system supporting zero-voltage charging. When the battery voltage of the battery independently used or the system voltage of the multi battery system made of batteries in series and parallel is zero, the user can restore the battery system to normal through the series and parallel battery system supporting zero-voltage charging, which makes the battery system to be charged to a level suitable for normal use.

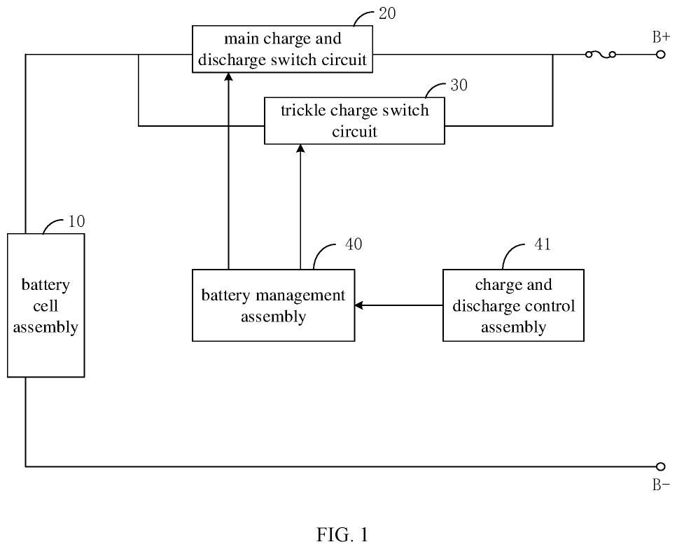

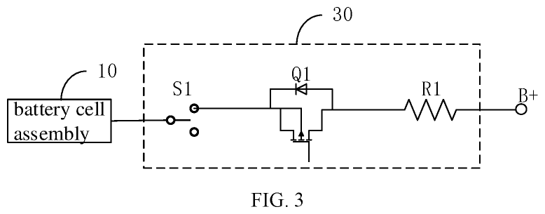

Referring to FIG. 1 and FIG. 3, in an embodiment of the present application, the lithium battery for the series and parallel battery system supporting zero-voltage charging includes: a battery cell assembly 10, a main charge and discharge switch circuit 20, and a trickle charge switch circuit 30.

The main charge and discharge switch circuit 20 is provided in series between the battery cell assembly 10 and a power supply end, and is configured to control an electrical connection between the battery cell assembly 10 and the power supply end in response to receiving a charge/discharge control signal.

The trickle charge switch circuit 30 is provided in parallel with the main charge and discharge switch circuit 20, and is configured to conduct a path between the battery cell assembly 10 and the power supply end in response to that the main charge and discharge switch circuit 20 disconnects the electrical connection between the battery cell assembly 10 and the power supply end, so that the battery cell assembly 10 can be trickle-charged in response to that the power supply end is connected to a charger 90.

The main charge and discharge switch circuit 20 can be any main charge and discharge switch circuit 20 that can control the electrical connection between the power supply end and the battery cell assembly 10 in response to receiving the charge/discharge control signal, such as a contactor, etc. In this embodiment, in response to receiving the charge/discharge control signal, the contactor can control the power supply end to be electrically connected to the battery cell assembly 10 so that the battery cell assembly 10 charges or discharges. It should be noted that when the user triggers a charge and discharge control assembly 41, the charge/discharge control signal is output by the charge and discharge control assembly 41 to a battery management assembly 40, and transmitted to the main charge and discharge switch circuit 20 through the battery management assembly 40, so as to control an on/off of the main charge and discharge switch circuit 20.

In this embodiment, the trickle charge switch circuit 30 can be a current-limiting resistor R1, a switching tube Q1, and a relay S1. One end of the current-limiting resistor R1 is connected to the power supply end, a first end of the switching tube Q1 is connected to the relay S1, a second end of the switch Q1 is connected to the other end of the current-limiting resistor R1, and the other end of the relay S1 is connected to the battery cell assembly 10. Further, the switching tube Q1 is a power tube. The relay S1 is a normally turned off, when the normally off relay S1 is not energized or does not operate, a contact is turned off, that is, it is connected. It can be understood that in response to that the lithium battery is shut down, the main charge and discharge switch circuit 20 cannot receive the charge/discharge control signal, that is, the power supply end is electrically disconnected from the battery cell assembly 10. At this time, the trickle charge switch circuit 30 conducts the path between the battery cell assembly 10 and the power supply end, that is, the relay S1 is turned on and the power tube is turned off. Because the power tube has a body diode, in response to that the charger 90 is connected to the power supply end, a low current flows through the body diode to trickle charge the battery cell assembly 10, so that the lithium battery in zero voltage can return to a normal working condition.

In this embodiment, when the voltage of the lithium battery drops to 0V due to over-discharge or self-discharge during long-term storage, the battery management assembly 40 cannot start to work, and therefore cannot output the charge/discharge control signal to control the main charge and discharge switch circuit 20, but the trickle charge switch circuit 30 can conduct the path between the battery cell assembly 10 and the power supply end through the battery management assembly 40, then the battery cell assembly 10 enters a state that allows the current to flow in, and the charger 90 is connected to the power supply end to charge the lithium battery in zero-voltage to the normal working condition through the low current trickle charge method.

In the present application, the trickle charge switch circuit 30 conduct a trickle charge path between the battery cell assembly 10 and the power supply end in response to that the main charge and discharge switch circuit 20 disconnects the electrical connection between the battery cell assembly 10 and the power supply end, so that the battery cell assembly 10 is trickle-charged in response to that the charger 90 is connected to the power supply. Thus the charger uses the low current to trickle-charge the battery cell assembly 10 so that the lithium battery can resume normal operation on its own, which solves the problem that lithium batteries cannot be charged when in zero voltage due to long-term over-discharge and other reasons, and improves the user's convenience.

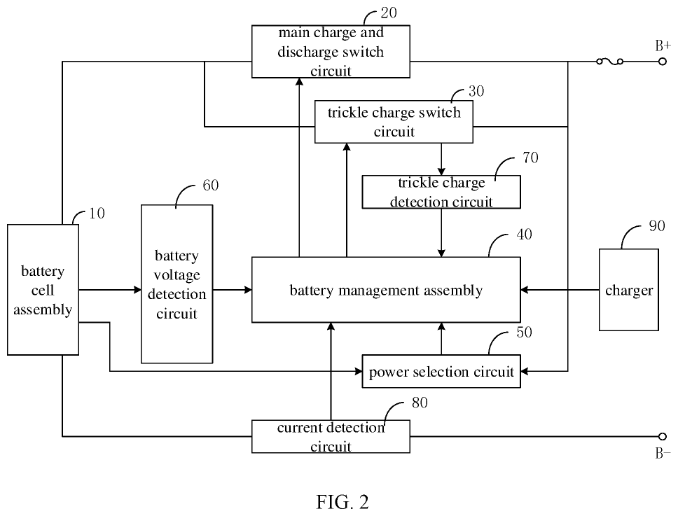

Referring to FIG. 2, in an embodiment, the lithium battery for the series and parallel battery system supporting zero-voltage charging also includes: the battery management assembly 40 and a power selection circuit 50.

An input end of the power selection circuit 50 is respectively connected to the battery cell assembly 10 and the power supply end, and an output end of the power selection circuit 50 is connected to the battery management assembly 40. The power selection circuit 50 is configured to select one of the battery cell assembly 10 and the power supply end to provide power supply to the battery management assembly 40 according to a voltage value of the battery cell assembly 10.

In this embodiment, the battery management assembly 40 can be a main controller, such as a microprogrammed control unit (MCU), a digital signal processor (DSP), a field programmable gate array (FPGA) and a system on chip (SOC), etc. The power selection circuit 50 can be a diode, that is, an anode of the diode is connected to the battery cell assembly 10 or the power supply end, etc., and a cathode of the diode is connected to the battery management assembly 40. It can be understood that when the lithium battery operates normally, the battery cell assembly 10 provides power to the battery management assembly 40; in response to that the battery management assembly 40 connected to the battery cell assembly 10 is not connected to an auxiliary power supply of the charger 90, the trickle charge current formed by the trickle charge switch circuit 30 can be conducted to provide power supply to the battery management assembly 40, so that the battery management assembly 40 can access the power supply to work.

Referring to FIG. 2, in an embodiment, the lithium battery for the series and parallel battery system supporting zero-voltage charging also includes: a trickle charge detection circuit 70. A detection end of the trickle charge detection circuit 70 is connected to the trickle charge switch circuit 30, and an output end of the trickle charge detection circuit 70 is connected to the battery management assembly 40, and the trickle charge detection circuit 70 is configured to detect a working state of the trickle charge switch circuit 30 and output a corresponding trickle charge detection signal to the battery management assembly 40.

The battery management assembly 40 is configured to identify the corresponding working state of the trickle charge switch circuit 30 according to the trickle charge detection signal.

The trickle charge detection circuit 70 can be any detection circuit that can detect the working state of the trickle charge switch circuit 30. In this embodiment, the trickle charge detection circuit 70 can be a comparator. A positive input end of the comparator is connected to one end of the current-limiting resistor R1, a negative input end of the comparator is connected to the other end of the current-limiting resistor R1, and an output end of the comparator is connected to the battery management assembly 40. The comparator is configured to compare the voltage at one end of the current-limiting resistor R1 with the voltage at the other end of the current-limiting resistor R1 and output a trickle charge detection signal to the battery management assembly 40. In this embodiment, the trickle charge detection circuit 70 is configured to detect the trickle charge current flowing through the trickle charge switch circuit 30, that is, the trickle charge current flowing through the current-limiting resistor R1 is detected, and the trickle charge detection signal is output to the battery management assembly 40. In this way, when a trickle charge current flows through the current-limiting resistor R1, the trickle charge detection circuit 70 outputs a high-level trickle charge detection signal; when there is no trickle charge current flowing through the current-limiting resistor R1, the trickle charge detection circuit 70 outputs a low-level trickle charge detection signal. The battery management assembly 40 can know that the trickle charge switch circuit 30 is in the on state through the high-level trickle charge detection signal, or can know that the trickle charge switch circuit 30 is in the off state through the low-level trickle charge detection signal, thus the working state of the trickle charge switch circuit 30 is known in real time.

Referring to FIG. 2, in an embodiment, the lithium battery for the series and parallel battery system supporting zero-voltage charging also includes: a battery voltage detection circuit 60 connected to the battery cell assembly 10. The battery voltage detection circuit 60 is configured to detect the voltage of the battery cell assembly 10 to obtain a voltage of the plurality of battery cell assemblies and output a battery voltage detection signal.

The battery management assembly 40 is also configured to communicate with the charger 90 during power-on operation, and control the trickle charge switch circuit 30 to operate and output a real-time trickle charge current request to the charger 90 in response to that the voltage is determined to be lower than a preset voltage according to the battery voltage detection signal, and control the trickle charge switch circuit 30 to stop in response to that the voltage is determined to be higher than or equal to the preset voltage according to the battery voltage detection signal.

The battery voltage detection circuit 60 can be any battery voltage detection assembly that can detect the voltage of the battery cell assembly 10, such as a bleeder circuit. Compared with integrated chips, the battery voltage detection circuit 60 is built with discrete elements, so that a detection channel of the battery voltage detection circuit 60 can be set according to actual needs, and the cost is lower.

In this embodiment, the battery voltage detection circuit 60 detects the voltage of the battery cell assembly 10 to obtain the voltage of the plurality of battery cell assemblies, and outputs the corresponding battery voltage detection signal. In response to that the voltage is determined to be lower than the preset voltage according to the battery voltage detection signal, the battery management assembly 40 controls the trickle charge switch circuit 30 to operate and output the real-time trickle charge current request to the charger 90. In response to that the voltage is determined to be higher than or equal to the preset voltage according to the received battery voltage detection signal, the battery management assembly 40 outputs the charge control signal to control the trickle charge switch circuit 30 to stop and disconnect the path between the battery cell assembly 10 connected through the trickle charge switch circuit 30 and the power supply end to stop trickle charging the battery cell assembly 10. At the same time, the power supply end is controlled to be electrically connected to the battery cell assembly 10 by the main charge and discharge switch circuit 20, thereby charging the battery cell assembly 10 normally.

Referring to FIG. 2, in an embodiment, the lithium battery for the series and parallel battery system supporting zero-voltage charging also includes a current detection circuit 80. A detection end of the current detection circuit 80 is connected to the battery cell assembly 10, an output end of the current detection circuit 80 is connected to the battery management assembly 40, and the current detection circuit 80 is configured to detect a current flowing through the battery cell assembly 10 and outputs a current detection signal.

The battery management assembly 40 is also configured to output a real-time trickle current request to the charger 90 according to the current detection signal.

In actual applications, due to the failure of the battery management assembly 40 or the charger 90 and the trickle charge current transmitted from the charger 90 to the battery cell assembly 10 is lost during the transmission process, there may be a certain deviation between the requested trickle current by the battery management assembly 40 and the actually received trickle charge current by the battery cell assembly 10. Therefore, the current detection circuit 80 is provided between the battery cell assembly 10 and the trickle charge switch circuit 30 to detect the trickle current flowing into the battery cell assembly 10.

The current detection circuit 80 can be any current detection circuit 80 that can detect the trickle charge current flowing into the battery cell assembly 10, such as a resistor. It should be noted that in order to reduce a voltage drop effect caused by the resistor, the current detection circuit 80 can be a current sensing resistor with a smaller resistance, such as a current sensing resistor below 5 mΩ.

In this embodiment, the current detection circuit 80 detects the trickle charge current flowing into the battery cell assembly 10. The battery management assembly 40 is powered on, and is communicated with the charger 90, then outputs a real-time trickle charge current request to the charger 90 according to the received current detection signal, so that the trickle charge current received by the lithium battery is closer to the actual requested trickle charge current, thereby improving the accuracy of charging the lithium battery by the charger 90.

The present application also provides a series and parallel battery system supporting zero-voltage charging, including a plurality of lithium batteries connected in series and parallel with each other. The specific structure of the lithium battery for the series and parallel battery system supporting zero-voltage charging refers to the above-mentioned embodiment. Since the series and parallel battery system supporting zero-voltage charging adopts all the technical solutions of all the above-mentioned embodiments, it has at least all the beneficial effects brought by technical solutions of the above-mentioned embodiments, which will not be repeated here.

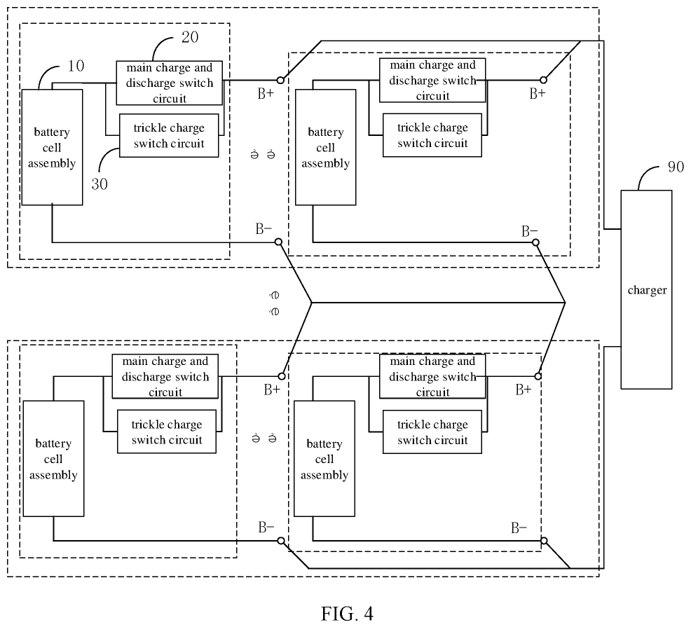

Referring to FIG. 3 and FIG. 4, in a single battery supporting zero-voltage charging, the trickle charge switch circuit 30 is composed of the relay S1, a metal oxide semiconductor (MOS) tube, and the current-limiting resistor R1. When the battery is in normal use alone, the contactor is turned on to provide a channel for electric energy input and output, and the trickle charge switch circuit 30 is completely off, allowing neither current to flow out nor current to flow in. When the battery is shut down, the contactor is disconnected, the relay S1 is connected, and the MOS tube is off. At this time, the power of the battery cannot be output, but due to the body diode of the MOS tube, the external current is allowed to flow into the battery through the current-limiting channel. It can be understood that when the voltage of the battery system drops to 0V due to over-discharge or self-discharge during long-term storage, the battery management assembly 40 cannot start to work, but the battery is in a state that allows current to flow in, that is, the charging direction of the trickle charge switch circuit 30 is turned on. At this time, the charger 90 is connected, and the zero-voltage battery can be charged to the normal working state through the low current trickle charge method.

Referring to FIG. 1 and FIG. 2, the series and parallel battery system supporting zero-voltage charging is constructed based on single cells supporting zero-voltage charging. Under normal operating conditions, the battery cell assembly 10 provides power for the battery management assembly 40. In response to that the voltage of the battery cell assembly 10 becomes 0V, the battery cell assembly 10 connected to the charger 90 automatically selects AUX_12V to provide power to the battery management assembly 40, while the battery cell assembly 10 not connected to the charger 90 uses the trickle charge current to provide power to the battery management assembly 40 through Vb+ formed by the trickle charge switch circuit 30.

The trickle charge detection circuit 70 is composed of the comparator, a negative end input protection diode, a negative end divider resistor, a positive end input protection diode, a positive end input step-down diode, a positive end voltage divider resistor, an anti-false triggering filter capacitor and an over-voltage protection diode. In response to there is the trickle charge current flowing through the current-limiting resistor R1, the trickle charge detection circuit 70 outputs a high level; in response to there is no trickle charge current flowing through the current-limiting resistor R1, the trickle charge detection circuit 70 outputs a low level.

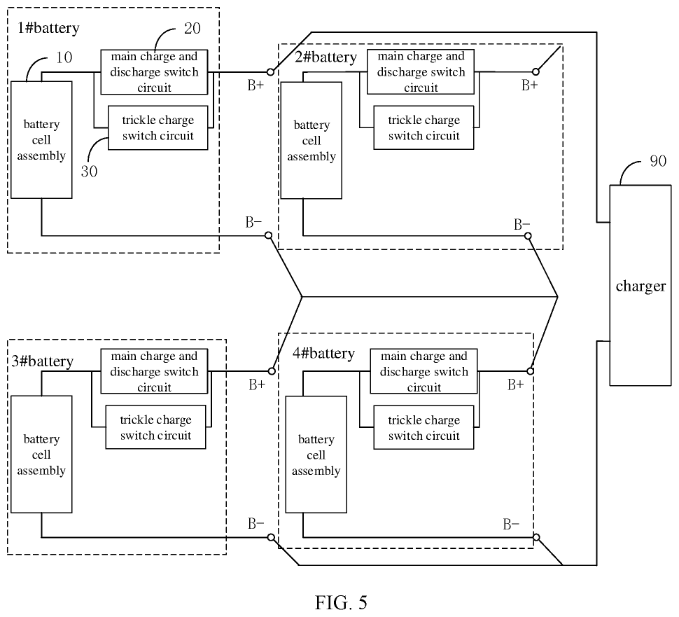

Referring to FIG. 2, FIG. 3 and FIG. 5, in a two-series and two-parallel battery system made of single cells supporting zero-voltage charging, the battery management assembly 40 of the battery cell assembly 10 with different attributes and positions in the battery system obtain the working power supply to enter the working state through different working methods, and detects the trickle charge detection signal to identify the trickle charge state.

A 1# battery in a HIGHEST_VOLTAGE_GROUP attribute battery is connected to the charger 90. The battery management assembly 40 can directly use the AUX_12V of the charger 90 as the working power supply. After the battery management assembly 40 enters the working state, the relay S1 and the MOS tube are turned on, and the trickle charge flow circuit of the charger 90 is turned on. A 2# battery with the same HIGHEST_VOLTAGE_GROUP attribute uses Vb+ as the working power supply to enter the working state after the 1# battery turns on the relay S1 and MOS tube. The 2# battery recognizes a waking and starting process of the battery system through parallel waking detection and turns on the relay S1 and MOS tube. Since the trickle charge flow circuit of the charger 90 is turned on, the trickle charge current output by the charger 90 will charge all the batteries through the trickle charge switch circuit 30. The battery management assembly 40 of the 2# battery recognizes the trickle charge state through the trickle charge detection signal. The battery management assembly 40 of a 3# battery a 4# battery with a LOW_VOLTAGE_GROUP attribute also uses the Vb+ as the working power supply to enter the working state, and recognizes the trickle charge state through the trickle charge detection signal.

There is no difference between the charging methods of single cells in zero-voltage and multi-series and parallel battery systems in zero-voltage. The battery connected to the charger 90 (the single cell in zero-voltage or a certain HIGHEST_VOLTAGE_GROUP battery of the multi-series and parallel battery system in zero-voltage) directly uses the AUX_12V of the charger 90 as the working power supply to enter the working state, and turns on the relay S1 and the MOS tube, that is, turns on the trickle charge switch circuit 30.

The battery connected to the charger 90 requests the charging current from the charger 90 according to the number of parallel connections of the batteries (the number of parallel connections is 1 for a single battery) and the size of the current-limiting resistor R1 in the trickle charge switch circuit 30. The basic principle of requesting the charging current from the charger 90: a sum of the voltage drops of the trickle charge current on all current-limiting resistors R1, plus a sum of all battery voltages, shall not be greater than a maximum output voltage allowed by the charger 90. It can be understood that after all batteries turn on the trickle charge switch circuit 30 and start charging, the battery voltage continues to rise. In order to prevent the total system voltage from exceeding the maximum output voltage of the charger 90, the batteries connected to the charger 90 adjust the trickle charge current in real time. After the battery voltage rises to 8.0V (taking a 12V lithium iron phosphate battery as an example), and the trickle charge process ends. All batteries turn on the contactors, disconnect the relay S1, turn off the MOS tube, and disconnect the trickle charge switch circuit 30. The main charge and discharge switch circuit 20 is turned on, and the charging process is transferred to normal until the charging is completed or terminated.

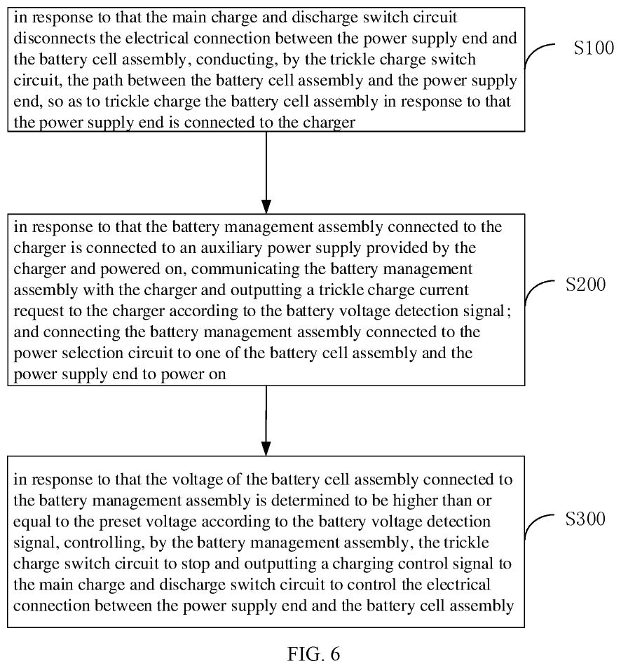

The present application also provides a charging method for the series and parallel battery system supporting zero-voltage charging. Referring to FIG. 1 to FIG. 6, in an embodiment of the present application, the charging method for the series and parallel battery system supporting zero-voltage charging includes the following steps:

S100, in response to that the main charge and discharge switch circuit 20 disconnects the electrical connection between the power supply end and the battery cell assembly 10, conducting, by the trickle charge switch circuit 30, the path between the battery cell assembly 10 and the power supply end, so as to trickle charge the battery cell assembly 10 in response to that the power supply end is connected to the charger 90.

In this embodiment, the series and parallel battery system supporting zero-voltage charging includes a plurality of lithium batteries connected in series and parallel with each other. In the present application, in response to that the main charge and discharge switch circuit 20 disconnects the electrical connection between the power supply end and the battery cell assembly 10, the trickle charge switch circuit 30 conducts the path between the battery cell assembly 10 and the power supply end, so as to trickle charge the battery cell assembly 10 in response to that the charger 90 is connected to the power supply end, and the battery can return to normal by itself. In this way, the user can return the battery system to normal by themselves, thereby improving the user's convenience.

In this embodiment, in response to that the voltage of the battery in the battery system drops to 0V due to over-discharge or self-discharge during long-term storage, the battery management assembly 40 cannot start to work, and therefore cannot output the charging/discharge control signal to control the main charge and discharge switch circuit 20, then the main charge and discharge switch circuit 20 cannot receive the charge/discharge control signal, that is, the power supply end is electrically disconnected from the battery cell assembly 10. At this time, the battery management assembly 40 is connected to the auxiliary power supply of the charger 90 to power on, and the trickle charge switch circuit 30 is controlled to conduct the trickle charge path between the battery cell assembly 10 and the power supply end, that is, the relay S1 is turned on and the power tube is turned off. Since the power tube is provided with the body diode, in response to that the charger 90 is connected to the power supply end, the battery system in zero-voltage can be charged to the normal working state through the low current trickle charge method.

Referring to FIG. 1 to FIG. 6, in an embodiment of the present application, the charging method for the series and parallel battery system supporting zero-voltage charging further includes:

S200, in response to that the battery management assembly 40 connected to the charger 90 is connected to an auxiliary power supply provided by the charger 90 and powered on, communicating the battery management assembly 40 with the charger 90 and outputting a trickle charge current request to the charger 90 according to the battery voltage detection signal; and
connecting the battery management assembly 40 connected to the power selection circuit 50 to one of the battery cell assembly 10 and the power supply end to power on.

It can be understood that when the battery system operates normally, the battery cell assembly 10 provides power supply to the battery management assembly 40. In response to that the voltage of the battery cell assembly 10 becomes 0V and the auxiliary power supply of the charger 90 is not connected, the trickle charge current conducted by the trickle charge switch circuit 30 can provide power supply to the battery management assembly 40 to drive the battery management assembly 40 to work. In addition, when connected to the charger 90, the battery management assembly 40 can directly access the auxiliary power supply of the charger 90 to power on.

Further, the charging method for the series and parallel battery system supporting zero-voltage charging also includes: S300, in response to that the voltage of the battery cell assembly 10 connected to the battery management assembly 40 is determined to be higher than or equal to the preset voltage according to the battery voltage detection signal, controlling, by the battery management assembly 40, the trickle charge switch circuit to stop and outputting a charging control signal to the main charge and discharge switch circuit 20 to control the electrical connection between the power supply end and the battery cell assembly 10.

In this embodiment, the battery voltage detection circuit 60 detects the voltage of the battery cell assembly 10 to obtain the voltage of the plurality of battery cell assemblies, and outputs the corresponding battery voltage detection signal. In response to that the voltage is determined to be higher than or equal to the preset voltage according to the received battery voltage detection signal, the battery management assembly 40 outputs the charge control signal to control the trickle charge switch circuit 30 to stop and disconnect the path between the battery cell assembly 10 connected through the trickle charge switch circuit 30 and the power supply end to stop trickle charging the battery cell assembly 10. At the same time, the power supply end is controlled to be electrically connected to the battery cell assembly 10 by the main charge and discharge switch circuit 20, thereby charging the battery cell assembly 10 normally.

It can be understood that after all batteries turn on the trickle charge switch circuit 30 and start charging, the battery voltage continues to rise. In order to prevent the total system voltage from exceeding the maximum output voltage of the charger 90, the batteries connected to the charger 90 adjust the trickle charge current in real time. After the battery voltage rises to 8.0V (taking a 12V lithium iron phosphate battery as an example), the battery management assembly 40 turns off the trickle charge switch circuit 30, that is, turn off the relay S1 and the switching tube Q1 to stop the trickle charge of the battery cell assembly 10, and outputs the charging control signal to the main charge and discharge switch circuit 20, so that the battery system returns to normal charging state, thereby solving the problem that users cannot take measures on their own to deal with the situation where the battery system cannot be charged normally due to zero voltage, which improves the convenience of use and reduces costs.

The above descriptions are only embodiments of the present application, and are not intended to limit the scope of the present application. Under the inventive concept of the present application, any equivalent structural transformations made by using the contents of the description and drawings of the present application, or direct/indirect applications in other related technical fields are included in the scope of the present application.

What is claimed is:

1. A lithium battery for a series and parallel battery system supporting zero-voltage charging, comprising:
a battery cell assembly;
a main charge and discharge switch circuit provided in series between the battery cell assembly and a power supply end, and configured to control an electrical connection between the battery cell assembly and the power supply end in response to receiving a charge/discharge control signal; and
a trickle charge switch circuit provided in parallel with the main charge and discharge switch circuit, and configured to conduct a path between the battery cell assembly and the power supply end in response to that the main charge and discharge switch circuit disconnects the electrical connection between the battery cell assembly and the power supply end, so as to trickle charge the battery cell assembly in response to that the power supply end is connected to a charger.

2. The lithium battery for the series and parallel battery system supporting zero-voltage charging of claim 1, further comprising:
a battery management assembly; and
a power selection circuit, wherein an input end of the power selection circuit is respectively connected to the battery cell assembly and the power supply end, an output end of the power selection circuit is connected to the battery management assembly, and the power selection circuit is configured to select one of the battery cell assembly and the power supply end to supply power to the battery management assembly according to a voltage value of the battery cell assembly.

3. The lithium battery for the series and parallel battery system supporting zero-voltage charging of claim 2, further comprising:
a trickle charge detection circuit;
wherein a detection end of the trickle charge detection circuit is connected to the trickle charge switch circuit, an output end of the trickle charge detection circuit is connected to the battery management assembly, and the trickle charge detection circuit is configured to detect a working state of the trickle charge switch circuit and output a corresponding trickle charge detection signal to the battery management assembly; and
the battery management assembly is further configured to identify the working state of the corresponding trickle charge switch circuit according to the trickle charge detection signal.

4. The lithium battery for the series and parallel battery system supporting zero-voltage charging of claim 2, wherein the battery cell assembly comprises a plurality of battery cell assemblies, and the lithium battery for the series and parallel battery system supporting zero-voltage charging further comprises:
a battery voltage detection circuit connected to the battery cell assembly and configured to detect a voltage of the battery cell assembly to obtain a voltage of the plurality of battery cell assemblies and output a battery voltage detection signal; wherein
the battery management assembly is further configured to communicate with the charger during power-on operation, control the trickle charge switch circuit to operate and output a real-time trickle current request to the charger in response to that the voltage is determined to be lower than a preset voltage according to the battery voltage detection signal, and control the trickle charge switch circuit to stop in response to that the voltage is determined to be higher than or equal to the preset voltage according to the battery voltage detection signal.

5. The lithium battery for the series and parallel battery system supporting zero-voltage charging of claim 4, further comprising:
a current detection circuit;
wherein a detection end of the current detection circuit is connected to the battery cell assembly, and an output end of the current detection circuit is connected to the battery management assembly; the current detection circuit is configured to detect a current flowing through the battery cell assembly and output a current detection signal; and
the battery management assembly is further configured to output the real-time trickle current request to the charger according to the current detection signal.

6. The lithium battery for the series and parallel battery system supporting zero-voltage charging of claim 1, wherein the trickle charge switch circuit comprises a current-limiting resistor, a switching tube and a relay, one end of the current-limiting resistor is connected to the power supply end, a first end of the switching tube is connected to one end of the relay, a second end of the switching tube is connected to the other end of the current-limiting resistor, and the other end of the relay is connected to the battery cell assembly.

7. A series and parallel battery system supporting zero-voltage charging, comprising a plurality of lithium batteries for the series and parallel battery system supporting zero-voltage charging of claim 1 connected in series and parallel to each other.

8. A charging method for the series and parallel battery system supporting zero-voltage charging of claim 7, comprising:
in response to that the main charge and discharge switch circuit disconnects the electrical connection between the power supply end and the battery cell assembly, conducting, by the trickle charge switch circuit, the path between the battery cell assembly and the power supply end, so as to trickle charge the battery cell assembly in response to that the power supply end is connected to the charger.

9. The charging method for the series and parallel battery system supporting zero-voltage charging of claim 8, further comprising:
in response to that the battery management assembly connected to the charger is connected to an auxiliary power supply provided by the charger and powered on, communicating the battery management assembly with the charger and outputting a trickle charge current request to the charger according to the battery voltage detection signal; and
connecting the battery management assembly connected to the power selection circuit to one of the battery cell assembly and the power supply end to power on.

10. The charging method for the series and parallel battery system supporting zero-voltage charging of claim 9, further comprising:
in response to that the voltage of the battery cell assembly connected to the battery management assembly is determined to be higher than or equal to the preset voltage according to the battery voltage detection signal, controlling, by the battery management assembly, the trickle charge switch circuit to stop and outputting a charging control signal to the main charge and discharge switch circuit to control the electrical connection between the power supply end and the battery cell assembly.
